(19) United States
(12) Patent Application Publication
(10) Pub. No.: US 2021/0291582 A1
(43) Pub. Date: Sep. 23, 2021

(54) CASE FOR ELECTRONIC DEVICE, ELECTRONIC DEVICE INCLUDING SAME, AND METHOD FOR MANUFACTURING SAME

(71) Applicant: Samsung Electronics Co., Ltd., Gyeonggi-do (KR)

(72) Inventors: Sookyu LEE, Gyeonggi-do (KR); Jaewoong LIM, Gyeonggi-do (KR)

(21) Appl. No.: 17/258,513

(22) PCT Filed: Aug. 27, 2019
(86) PCT No.: PCT/KR2019/010944

§ 371 Date: Jan. 7, 2021

(30) Foreign Application Priority Data
Aug. 27, 2018 (KR) 10-2018-0100599

(51) Int. Cl. B44C 1/18; B05D 7/00; G06F 1/16; B29C 45/14; B29C 45/00

(52) U.S. Cl. CPC B44C 1/18; B05D 7/53; G06F 1/1628; B29L 2031/3406; B29C 45/0053; B29C 2045/14713; B29C 2045/0079; B29C 45/14688

(57) ABSTRACT

Introduced is a case for an electronic device, the case comprising: a base layer for configuring a basic frame; a first pattern layer formed on the base layer; a second pattern layer applied onto the first pattern layer; and a clear-painted layer which is applied to coat the first pattern layer or the second pattern layer. In addition, various other embodiments are possible.

### TECHNICAL FIELD

The disclosure relates to a case for an electronic device and, more particularly, to technology for implementing texture of a specific material on a surface of a case and performing surface treatment on the surface of the case to improve beauty and solidity of an electronic device.

### BACKGROUND ART

So far, electronic devices have been made slim and light along with the development of technology, and have been developed toward high performance so as to be able to conduct various functions.

In addition, recent electronic devices have been provided with functional elements as well as beautiful appearance design to appeal to consumers.

In applying various design elements to a surface of a case for the electronic device, research on the case for the electronic device capable of pursuing beauty and solidity and a method of manufacturing the same is under way.

### DETAILED DESCRIPTION OF INVENTION

### Technical Problem

A case for an electronic device capable of reflecting texture of various materials on a surface of the case for the electronic device to visual as well as tactile elements, and a method of manufacturing the same can be provided.

Especially, a case for an electronic device which requires to secure strength above a fixed level to protect various parts in the electronic device, thus implements texture of a fabric on a surface of the case for the electronic device which is formed by injecting a plastic series material, improves an aesthetic element, and has solidity preventing the texture of the fabric from being easily damaged, and a method of manufacturing the same can be provided.

### Solution to Problem

A case for an electronic device according to an embodiment of the disclosure may include: a base layer configuring a basic frame; a first pattern layer formed on the base layer; a second pattern layer applied onto the first pattern layer; and a clear-painted layer applied to coat the first pattern layer or the second pattern layer.

An electronic device according to an embodiment of the disclosure may include a plurality of cases in which a display, a circuit board, or an input means is mounted, wherein at least one or more cases of the plurality of cases may include: a base layer configuring a basic frame; a first pattern layer formed on the base layer; a second pattern layer applied onto the first pattern layer; and a clear-painted layer applied to coat the first pattern layer or the second pattern layer.

A method of manufacturing a case for an electronic device according to an embodiment of the disclosure may include: an operation of injection-molding a base layer and a first pattern layer into a metal mold on which a first pattern is processed; an operation of applying a second pattern layer; an operation of applying a clear-painted layer; and a dry operation.

### Advantageous Effects of Invention

A pattern in which visual and tactile elements are implemented on a case for an electronic device can be implemented. Durability of the implemented pattern is improved to be able to prevent the pattern from being damaged even upon continual use by a user.

### BRIEF DESCRIPTION OF DRAWINGS

FIG. 1 is a block diagram of an electronic device within a network environment in accordance with various embodiments of the disclosure;

FIG. 2 is a view conceptually illustrating a cross-sectional configuration of a case for an electronic device according to an embodiment of the disclosure;

FIG. 3 is a view illustrating an appearance of a case for an electronic device according to an embodiment of the disclosure; and

FIG. 4 is a flow chart of a method of manufacturing a case for an electronic device according to an embodiment of the disclosure.

### MODE FOR THE INVENTION

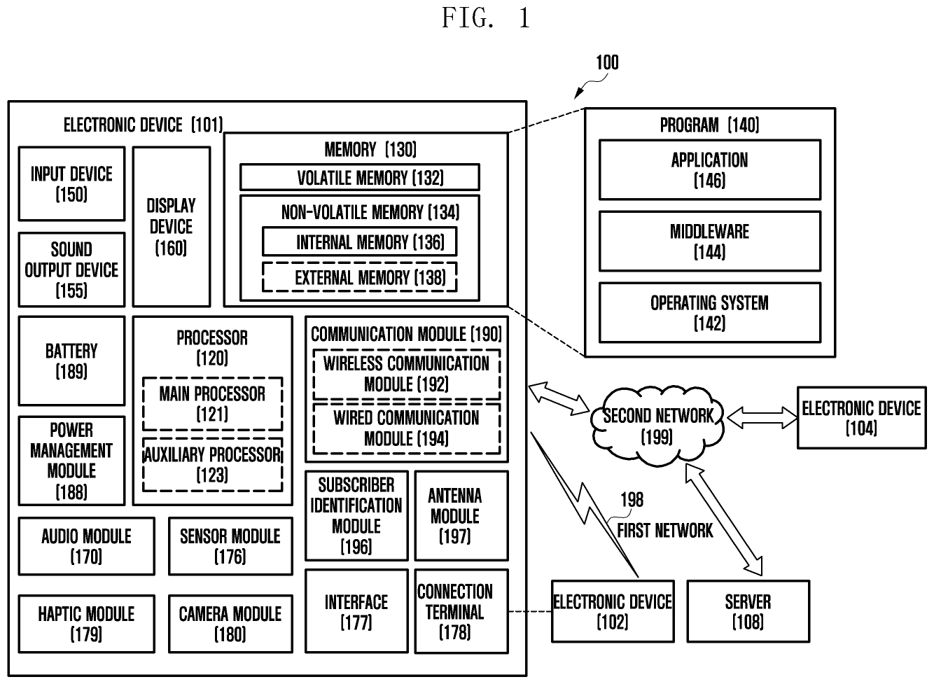

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input device 150, a sound output device 155, a display device 160, an audio module 170, a sensor module 176, an interface 177, a haptic module 179, a camera module 180, a power management module 188, a battery 189, a communication module 190, a subscriber identification module(SIM) 196, or an antenna module 197. In some embodiments, at least one (e.g., the display device 160 or the camera module 180) of the components may be omitted from the electronic device 101, or one or more other components may be added in the electronic device 101. In some embodiments, some of the components may be implemented as single integrated circuitry. For example, the sensor module 176 (e.g., a fingerprint sensor, an iris sensor, or an illuminance sensor) may be implemented as embedded in the display device 160 (e.g., a display).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), and an auxiliary processor 123 (e.g., a graphics processing unit (GPU), an image signal processor (ISP), a sensor hub processor, or a communication processor (CP)) that is operable independently from, or in conjunction with, the main processor 121. Additionally or alternatively, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display device 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input device 150 may receive a command or data to be used by other component (e.g., the processor 120) of the electronic device 101, from the outside (e.g., a user) of the electronic device 101. The input device 150 may include, for example, a microphone, a mouse, a keyboard, or a digital pen (e.g., a stylus pen).

The sound output device 155 may output sound signals to the outside of the electronic device 101. The sound output device 155 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display device 160 may visually provide information to the outside (e.g., a user) of the electronic device 101. The display device 160 may include, for example, a display, a hologram device, or a projector and control circuitry to control a corresponding one of the display, hologram device, and projector. According to an embodiment, the display device 160 may include touch circuitry adapted to detect a touch, or sensor circuitry (e.g., a pressure sensor) adapted to measure the intensity of force incurred by the touch.

The audio module 170 may convert a sound into an electrical signal and vice versa. According to an embodiment, the audio module 170 may obtain the sound via the input device 150, or output the sound via the sound output device 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., PCB). According to an embodiment, the antenna module 197 may include a plurality of antennas. In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 and 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, or client-server computing technology may be used, for example.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

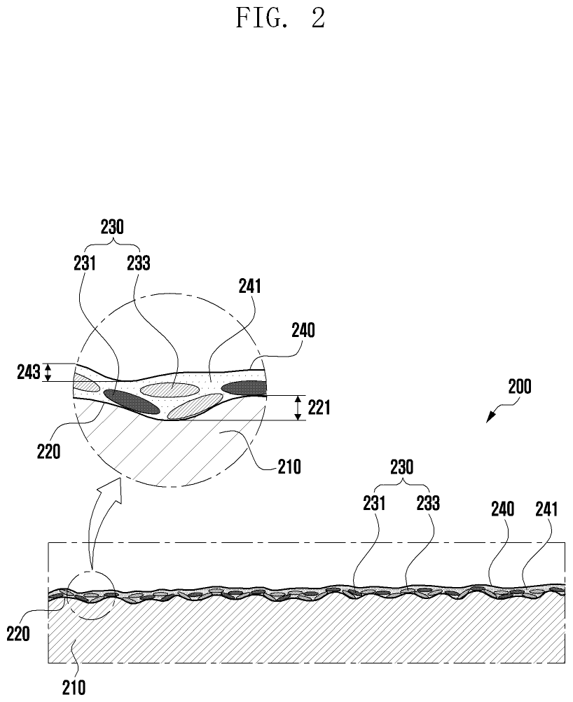

FIG. 2 is a view conceptually illustrating a cross-sectional configuration of a case 200 for an electronic device according to an embodiment of the disclosure.

A case 200 for an electronic device according to an embodiment of the disclosure may include a base layer 210, a first pattern layer 220, a second pattern layer 230, and a clear-painted layer 240.

The base layer 210 according to an embodiment of the disclosure may configure an overall appearance of the electronic device, and serve as a basic frame in which various parts can be mounted. The base layer 210 may be formed by injection molding using a metal mold. Polycarbonate (PC), acrylonitrile butadiene styrene (ABS), or a material in which the PC and the ABS are mixed may be used as a material of the base layer 210. In addition, various plastic materials that can be used for the injection molding may be used.

The first pattern layer 220 according to an embodiment of the disclosure may refer to, for instance, a fabric pattern, a metal hairline pattern, etc. as a specific shape that is to express the appearance of the electronic device. In an embodiment of the disclosure, the first pattern layer 220 may refer to the fabric pattern.

The first pattern layer 220 may be configured integrally with the base layer 210. A pattern of the first pattern layer 220 may be a first pattern. The first pattern layer 220 may be configured in such a way that it is engraved on a surface of the base layer 210 after the base layer 210 is processed, and may be integrally configured in an injection molding process by forming the first pattern on a metal mold for injection molding. In an embodiment of the disclosure, it may mean that the first pattern layer 220 can be integrally configured by the injection molding by forming the first pattern on the metal mold.

The first pattern may 3D scan a fabric textile, and actually reflect an irregular shape of the fabric textile. The shape of the fabric obtained in this way may be engraved by laser processing or an etching method, and a step 221 of the first pattern engraved on the metal mold may be configured to range from 100 μm to 300 μm. The first pattern layer 220 may be configured integrally with the base layer 210 by injection molding using the metal mold on which the first pattern is engraved, and the case 200 for the electronic device in which a basic shape of the fabric textile is implemented may be obtained.

The second pattern layer 230 according to an embodiment of the disclosure may be a painted layer that is partly applied to the first pattern layer 220. The second pattern layer 230 may be configured by applying at least two or more colors. The second pattern layer 230 may impart a visual effect to the case 200 for the electronic device. For example, the fabric textile may be more delicately implemented to the case 200 for the electronic device by implementing a three-dimensional shape of the fabric textile via the first pattern layer 220 and implementing a visual element based on the colors via the second pattern layer 230.

The second pattern layer 230 may be a dot pattern. The dot pattern having various sizes and colors may be implemented by spraying in a scattered way using a plurality of nozzles. For example, the second pattern layer 230 according to an embodiment of the disclosure may be configured by applying two colors in various sizes using a plurality of nozzles in order. For example, a first color 231 and a second color 233 may be applied in order. Therefore, the second pattern layer 230 may be partly applied without being applied to the entire first pattern layer 220, and different colors of the dot pattern constituting the second pattern layer 230 may overlap each other, whereby an overlapped new color may be expressed.

The clear-painted layer 240 according to an embodiment of the disclosure may be applied on the first pattern layer 220 and the second pattern layer 230 as a whole, and may protect the first pattern layer 220 and the second pattern layer 230. The clear-painted layer 240 may be applied such that the step 221 of the first pattern layer 220 and a step 243 of the dot pattern constituting the second pattern layer 230 are preserved. Fine particles 241 formed of acryl or urethane may be added and applied to the clear-painted layer 240 together. The added fine particles 241 may be partly exposed to a surface of the clear-painted layer 240, and be transmitted to a user by a touch. As a result, a touch of the fabric textile may be implemented to the case 200 for the electronic device.

The clear-painted layer 240 according to an embodiment of the disclosure may be applied to obtain a thickness, for instance, between 10 μm and 40 μm, and be then dried and cured at a temperature between 50° C. and 80° C.

As above, visual and tactile elements may be implemented on a surface of the case 200 for the electronic device according to an embodiment of the disclosure via the first pattern layer 220, the second pattern layer 230, and the clear-painted layer 240.

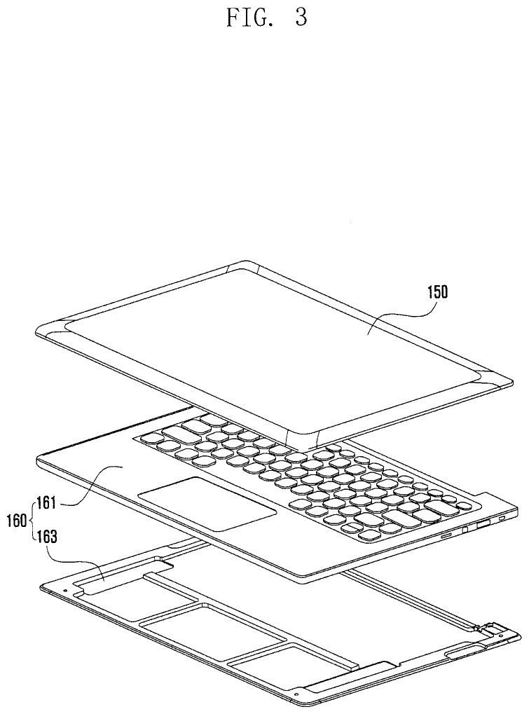

FIG. 3 is a view illustrating a case for an electronic device according to an embodiment of the disclosure.

An electronic device according to an embodiment of the disclosure may include a first case 150 and a second case 160.

The electronic device according to an embodiment of the disclosure may refer to a laptop computer. The first case 150 may be a case including a display. The second case 160 may be hinged to the first case 150, and may have an input means such as a keyboard, a main board, electronic parts such as CPU, etc. mounted therein.

The second case 160 may include an upper case 161 and a lower case 163. The input means such as a keyboard may be exposed to the upper case 161, and the lower case 163 may be coupled with the upper case 161.

A shape of the fabric textile may be implemented to the upper case 161 of the second case 160 that is subjected to a most frequent touch with a hand of a user for a longest time among the above cases. As described above, a pattern of the fabric textile may be implemented via the first pattern layer 220, the second pattern layer 230, and the clear-painted layer 240. The fabric textile may be visually and tactilely implemented to a portion that is subjected to a most frequent touch with a user in the electronic device such that the user can feel an aesthetic sense while using the electronic device.

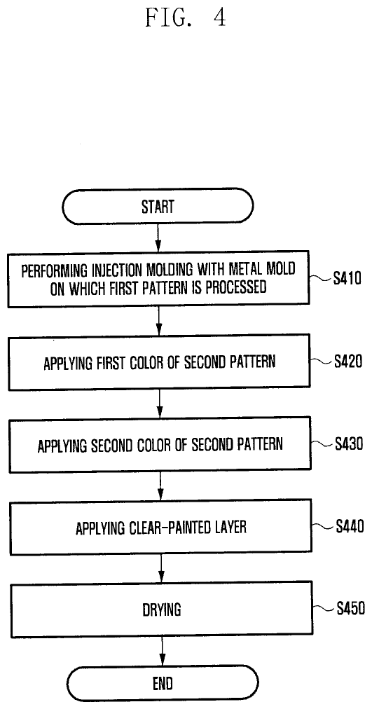

FIG. 4 is a flow chart of a method of manufacturing a case for an electronic device according to an embodiment of the disclosure. A case for an electronic device according to an embodiment of the disclosure may be manufactured by way of the following operations.

A base layer and a first pattern layer in which a first pattern is integrally formed may be obtained via operation S410 of performing injection molding via a metal mold on which the first pattern is processed.

Polycarbonate (PC), acrylonitrile butadiene styrene (ABS), or a material in which the PC and the ABS are mixed may be used as materials of the base layer and the first pattern layer.

For example, the first pattern may be processed on the metal mold via laser processing or an etching method, and a step 221 of the first pattern layer (see FIG. 2) may be processed to be within a range of 100 μm to 300 μm.

A shape of a fabric textile may be visually implemented via operations S420 and S430 of applying a second pattern layer on the first pattern layer. Various colors constituting the second pattern layer may be applied in order, and be configured to include at least two or more colors. For example, after a first color is applied (S420), a second color may be applied (S430). The fabric textile may be more delicately implemented while the plurality of colors of the second pattern layer overlap or are mixed with each other.

The first pattern layer and the second pattern layer may be protected via operation S440 of applying a clear-painted layer on the first pattern layer and the second pattern layer, and a tactile element of the fabric textile may be implemented via fine particles included in the clear-painted layer. For example, the clear-painted layer may be applied to have a thickness between 10 μm and 40 μm. The fine particles may be formed of, for instance, acryl or urethane.

The clear-painted layer may be cured via dry operation S450, and the first pattern layer and the second pattern layer may be protected even by a repeated touch by a user. The dry operation S450 may be performed, for instance, at a temperature between 50° C. and 80° C.

A case for an electronic device according to an embodiment of the disclosure may include: a base layer configuring a basic frame; a first pattern layer formed on the base layer; a second pattern layer applied onto the first pattern layer; and a clear-painted layer applied to coat the first pattern layer or the second pattern layer.

A first pattern of the first pattern layer may be injection-molded integrally with the base layer as a fabric pattern.

The second pattern layer may be configured as a painted layer that is partly applied onto the first pattern layer such that at least two or more colors are applied in order, and may be applied such that the two or more colors overlap in part.

The clear-painted layer may be configured to coat the first pattern layer and the second pattern layer such that a step of the first pattern layer and a step configured by the first pattern layer and the second pattern layer are preserved.

Fine particles may be included in the clear-painted layer, and the fine particles may be exposed to a surface of the clear-painted layer.

An electronic device according to an embodiment of the disclosure may include a plurality of cases in which a display, a circuit board, or an input means is mounted, wherein at least one or more cases of the plurality of cases may include: a base layer configuring a basic frame; a first pattern layer formed on the base layer; a second pattern layer applied onto the first pattern layer; and a clear-painted layer applied to coat the first pattern layer or the second pattern layer.

The plurality of cases may include a first case configured to include the display and a second case hinged to the first case, the second case may include an upper case to which the input means is exposed and a lower case coupled with the upper case, and at least one or more cases of the plurality of cases may be the upper case.

A first pattern of the first pattern layer may be injection-molded integrally with the base layer as a fabric pattern.

The second pattern layer may be configured as a painted layer that is partly applied onto the first pattern layer such that at least two or more colors are applied in order, and may be applied such that the two or more colors overlap in part.

The clear-painted layer may be configured to coat the first pattern layer and the second pattern layer such that a step of the first pattern layer and a step configured by the first pattern layer and the second pattern layer are preserved.

Fine particles may be included in the clear-painted layer, and the fine particles may be exposed to a surface of the clear-painted layer.

A method of manufacturing a case for an electronic device may include: an operation of injection-molding a base layer and a first pattern layer into a metal mold on which a first pattern is processed; an operation of applying a second pattern layer; an operation of applying a clear-painted layer; and a dry operation.

1. A case for an electronic device comprising:
a base layer configuring a basic frame;
a first pattern layer formed on the base layer;
a second pattern layer applied onto the first pattern layer; and
a clear-painted layer applied to coat the first pattern layer or the second pattern layer.

2. The case for an electronic device as claimed in claim 1, wherein a first pattern of the first pattern layer serves as a fabric pattern, and is injection-molded integrally with the base layer.

3. The case for an electronic device as claimed in claim 1, wherein the second pattern layer serves as a painted layer that is partly applied onto the first pattern layer, is configured such that at least two or more colors are applied in order, and is applied such that the two or more colors overlap in part.

4. The case for an electronic device as claimed in claim 1, wherein the clear-painted layer is configured to coat the first pattern layer and the second pattern layer such that a step of the first pattern layer and a step in which the first pattern layer and the second pattern layer are configured are preserved.

5. The case for an electronic device as claimed in claim 4, wherein fine particles are included in the clear-painted layer, and the fine particles are exposed to a surface of the clear-painted layer.

6. An electronic device comprising
a plurality of cases in which a display, a circuit board, or an input means is mounted,
wherein at least one or more cases of the plurality of cases comprise:
a base layer configuring a basic frame;
a first pattern layer formed on the base layer;
a second pattern layer applied onto the first pattern layer; and
a clear-painted layer applied to coat the first pattern layer or the second pattern layer.

7. The electronic device as claimed in claim 6,
wherein the plurality of cases include a first case configured to include the display and a second case hinged to the first case,
wherein the second case includes an upper case to which the input means is exposed and a lower case coupled with the upper case, and
wherein at least one or more cases of the plurality of cases are the upper case.

8. The electronic device as claimed in claim 6, wherein a first pattern of the first pattern layer is injection-molded integrally with the base layer as a fabric pattern.

9. The electronic device as claimed in claim 6, wherein the second pattern layer is configured as a painted layer that is partly applied onto the first pattern layer such that at least two or more colors are applied in order, and is applied such that the two or more colors overlap in part.

10. The electronic device as claimed in claim 6, wherein the clear-painted layer is configured to coat the first pattern layer and the second pattern layer such that a step of the first pattern layer and a step configured by the first pattern layer and the second pattern layer are preserved.

11. The electronic device as claimed in claim 10, wherein fine particles are included in the clear-painted layer, and are exposed to a surface of the clear-painted layer.

12. A method of manufacturing a case for an electronic device comprising:
an operation of injection-molding a base layer and a first pattern layer into a metal mold on which a first pattern is processed;
an operation of applying a second pattern layer;
an operation of applying a clear-painted layer; and
a dry operation.

13. The method as claimed in claim 12, further comprising an operation of engraving a shape of the first pattern, which is obtained by 3D scanning a fabric textile, using laser processing or an etching method.

14. The method as claimed in claim 12, wherein the first pattern has a shape of a fabric textile.
